(19) United States
(12) Patent Application Publication
(10) Pub. No.: US 2005/0156655 A1
(43) Pub. Date: Jul. 21, 2005

(54) Apparatus and method for leakage compensation in thin oxide CMOS applications

(75) Inventors: David William Boerstler, Round Rock, TX (US); Eskinder Hailu, Austin, TX (US)

Correspondence Address: Gregory W. Carr, 670 Founders Square, 900 Jackson Street, Dallas, TX, 75202, US

(73) Assignee: International Business Machines Corporation, Armonk, NY (US)

(21) Appl. No.: 10/759,940

(22) Filed: Jan. 16, 2004

(51) Int. Cl. H03K 17/16

(52) U.S. Cl. 327/379

(57) ABSTRACT

A method, apparatus, and computer program are provided for correcting the voltage across a thin oxide Complementary Metal-Oxide Semiconductor (CMOS) capacitor. Due to ever-decreasing thicknesses of capacitors in CMOS applications, leakage through the capacitor by electron tunneling and impurities has become a significant problem. For example, in Phased Lock Loops (PLLs), leaky capacitors can cause static phase errors. To combat the problem, a scaled capacitor and current mirrors are used to provide a correction current to a leaky capacitor to maintain a proper voltages.

### TECHNICAL FIELD

The present invention relates generally to the field of Complementary Metal-Oxide Semiconductor (CMOS) technology and, more particularly, to ameliorating device current leakage.

### BACKGROUND

The progress of electronic circuits was accomplished partially, as a result of the downsizing of components, such as vacuum tubes, for more than a century. The downsizing of active or passive components decreases their capacitance, resulting in an increase of the circuit operating speed and decrease of its power consumption. The size reduction increases the component density in the circuit, and enhances parallel operation capability, resulting in another increase in the circuit speed.

Historically, Field Effect Transistor (FET) technology scaling trends seek to improve gate delay by about 30% and the reduction of transition-energy by approximately 30% to 65% per generation. Typically, this is accomplished by scaling supply voltages and/or shrinking the process technology. In developing semiconductors, maximum supply voltages are limited by gate oxide wear-out, and minimum supply voltage levels are typically set by practical noise-margin and performance considerations. The components, though, should maintain proper device behavior at smaller and smaller channel lengths and progressively thinner gate dielectrics, which is in turn dependent on maintaining an adequately large lateral-to-vertical aspect ratio for a device. Thus, the ability to scale semiconductor gate dielectrics can be limited by both the scalability of the supply voltage and the desire to preserve the device's aspect ratio.

Static Random Access Memory (SRAM) circuits, for example in sub-0.3 μm CMOS technologies, exhibit profound read sensitivities to increased leakage current. Due to the limited scalability in supply voltages in high-performance applications, high electric fields may develop across the thin (˜1.5 nm) Silicon Dioxide (SiO₂) gate oxide. This field distorts the silicon band gap, such that electrons may more easily travel from the valence to the conduction band, from the gate to the channel and body. This problem is known as tunneling. This tunneling current along with sub-threshold leakage mechanisms, combine to affect the buildup of a voltage differential between the SRAM's bit lines such that the current-sinking behavior of the selected SRAM cell's wordline means Negative-Channel FETs (NFETs) must contend with significant leakage current from the non-selected devices.

It can be difficult to predict the limit of the down-sizing, although the ultimate limit of the downsizing is the distance of atoms in silicon crystals and that is about 0.3 nm. Some signal moderation effect such as through a single atomic size gate electrode might be possible, but the moderated signal would be too weak to transfer to another node. In addition, there is no practical solution at this moment for interconnects to contact to such small atomic nodes. Thus, the limit of the downsizing is considered from the viewpoint of the integration of individual components into circuits.

Therefore, there is a need for a device that addresses at least some of the issues related to integration limits, performance limits, power increases, reliability factors and design/production costs until integrated devices development expands beyond CMOS type devices.

### SUMMARY OF THE INVENTION

The present invention provides a method for current leakage correction for a leaky capacitor. A voltage across the leaky capacitor is measured. The measured voltage to a scaled capacitor is provided, wherein the scaled capacitor has an area reduced by a scaling factor in comparison to the leaky capacitor. Also, a sustaining charge to the leaky capacitor is provided.

### BRIEF DESCRIPTION OF THE DRAWINGS

For a more complete understanding of the present invention, and the advantages thereof, reference is now made to the following Detailed Description taken in conjunction with the accompanying drawings, in which:

FIG. 1A is a block diagram depicting a circuit containing a thin oxide leaky capacitor;

FIG. 1B is a graph depicting an ideal voltage across a capacitor relative to a current pulse;

FIG. 2 is a timing diagram of Phased Lock Loop (PLL) filter capacitor voltage affected by a leakage current resulting in a static phase error; and

FIG. 3 is a block diagram depicting a leakage correction circuit coupled to a thin oxide leaky capacitor.

### DETAILED DESCRIPTION

In the following discussion, numerous specific details are set forth to provide a thorough understanding of the present invention. However, those skilled in the art will appreciate that the present invention may be practiced without such specific details. In other instances, well-known elements have been illustrated in schematic or block diagram form in order not to obscure the present invention in unnecessary detail. Additionally, for the most part, details concerning network communications, electromagnetic signaling techniques, and the like, have been omitted inasmuch as such details are not considered necessary to obtain a complete understanding of the present invention, and are considered to be within the understanding of persons of ordinary skill in the relevant art.

It is further noted that, unless indicated otherwise, all functions described herein may be performed in either hardware or software, or some combination thereof. In one embodiment, however, the functions can be performed by a processor, such as a computer or an electronic data processor, in accordance with code, such as computer program code, software, and/or integrated circuits that are coded to perform such functions, unless indicated otherwise. In the present specification, the same reference characters are used to refer to terminals, signal lines, and their corresponding signals.

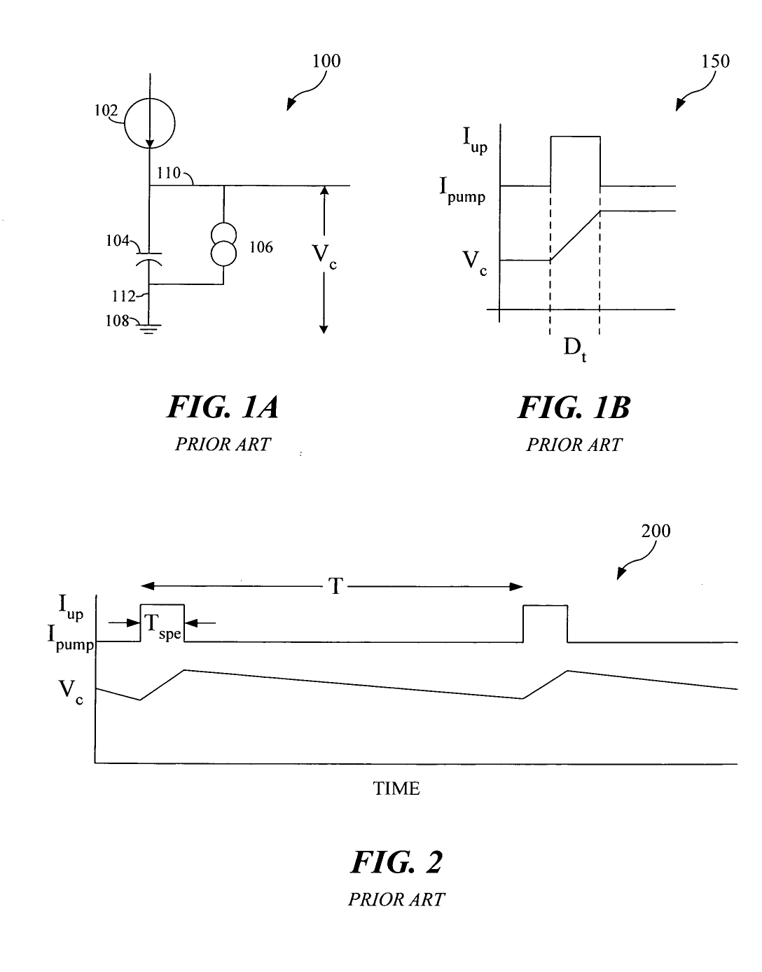

Referring to FIGS. 1A and 1B of the drawings, the reference numeral 100 generally designates a block diagram depicting a circuit containing a thin oxide leaky capacitor. Also, the reference numeral 150 generally designates is a graph depicting an ideal voltage across a capacitor relative to a current pulse. The circuit 100 comprises a current source 102, a capacitor 104, a first leakage current source 106, and ground 108.

The circuit 100 is utilized in a variety of applications, such as PLLs. However, as a result of the thin film dielectric in the capacitor 104, leakage current across the capacitor 104 can substantially affect the behavior of the capacitor. The intention in the circuit 100 is to generate a voltage V_{c} of FIG. 1B across the capacitor 104 of FIG. 1A that is proportional to the width of a current pulse Δt of FIG. 1B.

If a high impedance path (not shown) is provided at the first node 110 between the current source 102 and the capacitor 104, then for hold states when the impedance is high, the voltage V_{c} of FIG. 1B across the capacitor 104 of FIG. 1A decreases due to leakage. In other words, when the current source 104 is effectively “shut off,” the V_{c} of FIG. 1B across the capacitor 104 of FIG. 1A decreases at a rate higher than the normal rate of capacitive discharge. Thus, the voltage V_{c} of FIG. 1B across the capacitor 104 of FIG. 1A is as follows:

$$Vc = \frac{1}{C} \int Iup \cdot ⅆ t - \frac{1}{C} \int Ileak \cdot ⅆ t + Vc ( 0 ) \qquad ( 1 )$$

V_{c} is the output voltage across the capacitor. C is the electrical capacitance in Farads. Iₗₑₐₖ is the leakage current in Amperes. Iᵤₚ is the height of the rise of current during the leading edge of a clock signal, and dt is the change in time (also known as D (delta time).

The circuit 100 operates by driving a current across a capacitor 104. A current source or charge pump 102 provides a current to a first node 110. Also, the current source 102 can be either a negative charge source or a positive charge source. A capacitor 104 is coupled to the first node 110 and to ground 108 at a second node 112. The charge leakage is represented by the first leakage current source 106. The first leakage current source 106 is coupled at first end to the first node 110 and at a second end to the second node 112.

Referring to FIG. 2 of the drawings, the reference numeral 200 generally designates a timing diagram of PLL filter capacitor voltage affected by a leakage current resulting in a static phase error. In general, thin oxide capacitors do not have ideal electrical characteristics due to tunneling leakage.

Although the tunneling leakage is exponentially related to the voltage V_{c2} across a capacitor (not shown), FIG. 2 is shown as a lineal representation. Also, I_{UP} and I_{PUMP} are the height of the rise of current during the leading edge of a clock signal and a supply current, respectively. Since the capacitor voltage decreases due to leakage during the hold period of T minus T_{SPE}, a phase error T_{SPE} develops which the phase lock loop tries to correct at the next reference clock cycle, according to the following formula:

$${\int }_{0}^{Tspe} Iup \cdot ⅆ t = {\int }_{Tspe}^{T} Ileak \cdot ⅆ t \qquad ( 2 )$$

This static phase error (SPE) results in a continuous phase error between the reference clock and the PLL feedback clock, causing tracking and cycle-cycle jitter, a potentially unstable loop and system failure.

Currently, several different methods are available to attempt to moderate or reduce the impact of SPE on a circuit. One method involves reducing leakage current across a capacitor (not shown) by reducing the capacitor area. However, this method can degrade loop performance since other loop parameters must be increased to compensate for a reduction in capacitance. Thicker oxides can be used, though these can introduce additional costs of manufacturing. Increasing a supply current I_{PUMP} may also result in difficulties maintaining optimal PLL characteristics. Lastly, adjustments to the reference clock frequency, though these suffer from an effective minimum in present systems of T≧˜2 nanoseconds.

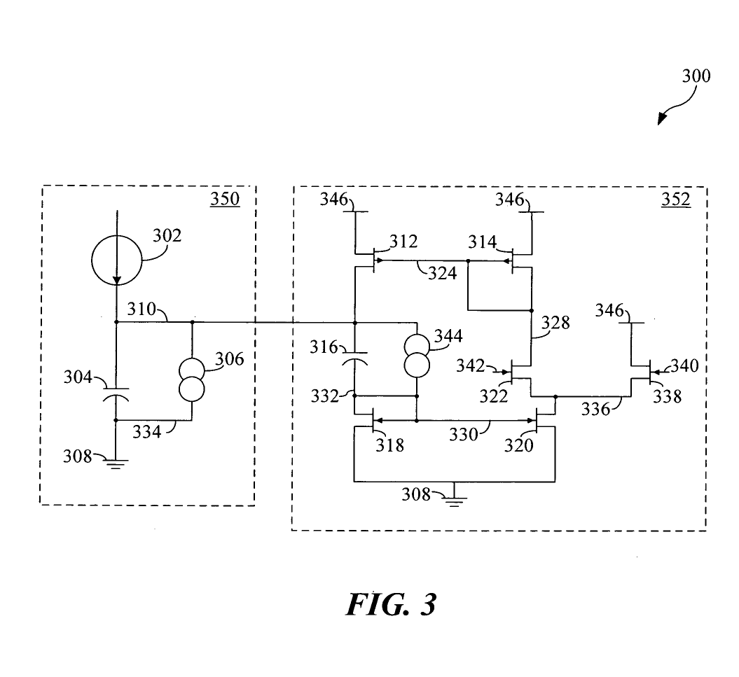

Referring to FIG. 3 of the drawings, the reference numeral 300 generally designates a block diagram depicting a leakage correction circuit coupled to a thin oxide leaky capacitor. The circuit 300 comprises a charge pump (CP) circuit 350 and a correction circuit 352. The CP 350 further comprises a current source 302, a first capacitor 304, ground 308, and a first leakage current source 306. The correction circuit 352 further comprises ground 308, a second capacitor 316, a second leakage current source 344, a first Positive-Channel Field Effect Transistor (PFET) 312, a second PFET 314, a first Negative-Channel Field Effect Transistor (NFET) 318, a second NFET 320, a third NFET 338, and a fourth NFET 322.

The CP 350 operates by driving a current across a capacitor 304. A current source or charge pump 302 provides a current to a first node 310. Also, the current source 302 can be either a negative charge source or a positive charge source. A capacitor 304 is coupled to the first node 310 and to ground 308 at a second node 334. The charge leakage is represented by the first leakage current source 306. The first leakage current source 306 is coupled at first end to the first node 310 and at a second end to the second node 334.

In comparison, the correction circuit 352 is more complicated than the CP 350. The correction circuit 352 is coupled to the CP 350 at the first node 310. The drain of the first PFET 312, a first end of the second leakage current source 344, and a first end of the second capacitor are coupled to the first node 310. A second end of the second capacitor 316 and a second end of the second current leakage source 344 are coupled at a third node 332 to the drain of the first NFET 318. Also, the gate of the first NFET 318 is coupled to the body of the first NFET 318 is coupled to the fourth node 330. The body of the second NFET 320 is also coupled to the fourth node 330. Also, the sources of the first NFET 318 and the second NFET 320 are coupled to ground 308.

In addition to the aforementioned connections, there are a variety of other connections that should be made for the current mirror 352 to operate. The drain of the second NFET 320, the source of the third NFET 338, and the source of the fourth NFET 322 are coupled to a fifth node 336. The drain of the third NFET 338, the source of the first PFET 312, and the source of the second PFET 314 are coupled to a voltage source 346. The drain of the fourth NFET 322, the drain of the second PFET 314, and the gate of the second PFET are coupled to a sixth node 328. The gate of the second PFET 314 is also coupled to the gate of the first PFET 312 through a seventh node 324.

The gates of the third NFET 338 and the fourth NFET 322 are then coupled to the CP 350 (not shown). The voltages input into the gate of the fourth NFET 322 at an eighth node 342 and into the gate of the third NFET 338 at a ninth node 340 vary depending on the state of the current source 302. If the current source is at a high impedance state, as described in FIG. 1, then an active high signal is input into the gate of the fourth NFET 322 at the eighth node 342. If the current source is not at a high impedance state, as described in FIG. 1, then an active high signal is input into the gate of the third NFET 338 at a ninth node 340.

The circuit 300 further maintains the voltage on the first capacitor 304 of the CP 350 by using the characteristics of the correction circuit 352. The first capacitor 304 has a first area (A) and a first capacitance (C) associated with it. The second capacitor 316 is a replica of the first capacitor 304 with a second area (A/N) and a second capacitance (C/N), where N is a scaling factor. The width (W) and length (L) of the current mirror 350 is varied such that the voltage across the second capacitor 316 is substantially equal to the voltage across the first capacitor 304. Therefore, since the voltage across the second capacitor 316 is substantially equal to the voltage across the first capacitor 304 and since the area of the second capacitor 316 is decreased by a factor of N, then the charge leakage represented by the second leakage current source 316 is also decreased by a factor of N (Iₗₑₐₖ/N).

The reduced current can then be multiplied by N+1 by using N+1 identical mirror devices in parallel. The identical mirrors comprise the second NFET 320, the third NFET 338, the fourth NFET 322, and the second PFET 314. Also, a device with a width ((N+1)W) to develop a tail current equal to a second reduced current ((N+1)Iₗₑₐₖ/N) for a the first PFET 312.

The first PFET 312 is configured such that a first reduced current ((N+1)Iₗₑₐₖ/N) is injected into first node 310 using additional current mirrors to exactly compensate the leakage of the first capacitors 304 and the second capacitor 316 during the hold state. In this manner the effective leakage current is reduced to zero. Additional area required by the circuit is negligible since N can be large and the mirror devices can be small.

It will further be understood from the foregoing description that various modifications and changes may be made in the preferred embodiment of the present invention without departing from its true spirit. This description is intended for purposes of illustration only and should not be construed in a limiting sense. The scope of this invention should be limited only by the language of the following claims.

1. An apparatus for current leakage correction coupled to a leaky capacitor, comprising:
a scaled capacitor, wherein the scaled capacitor has an area reduced by a scaling factor in comparison to the leaky capacitor; and
a plurality of current mirrors, wherein the plurality of current mirrors further comprise:
at least one current mirror is at least configured to be coupled to the leaky capacitor; and
at least one current mirror is at least configured to be coupled to the scaled capacitor that is at least configured to provide a potential difference across the scaled capacitor that is substantially equal to a potential difference across the leaky capacitor.

2. The apparatus of claim 1, wherein the plurality of current mirror further comprises a plurality of transistors.

3. The apparatus of claim 1, wherein the plurality of current mirrors further comprises a plurality of Field Effect Transistors (FET).

4. The apparatus of claim 3, wherein at least one FET of the plurality of FETs is a Positive-Channel FET (PFET), wherein the PFET is at least configured to inject current into the leaky capacitor to compensate for a current leak.

5. The apparatus of claim 4, wherein at least one FET of the plurality of FETs is a Negative-Channel FET (NFET).

6. The apparatus of claim 3, wherein at least one FET of the plurality of FETs is a Negative-Channel FET (NFET).

7. The apparatus of claim 1, wherein the plurality of current mirrors further comprise a plurality of bipolar transistors.

8. The apparatus of claim 1, wherein the plurality of current mirrors further comprise a plurality of Metal-Oxide Semiconductor FETs (MOSFETs).

9. The apparatus of claim 8, wherein at least one MOSFET of the plurality of MOSFETs is a Positive-type MOSFET (P-type MOSFET), wherein the P-type MOSFET is at least configured to inject current into the leaky capacitor to compensate for a current leak.

10. The apparatus of claim 9, wherein at least one FET of the plurality of FETs is a Negative-type MOSFET (N-type MOSFET).

11. The apparatus of claim 8, wherein at least one FET of the plurality of FETs is a Negative-Channel FET (NFET).

12. A method for current leakage correction for a leaky capacitor, comprising:
measuring voltage across the leaky capacitor;
providing the measured voltage to a scaled capacitor, wherein the scaled capacitor has an area reduced by a scaling factor in comparison to the leaky capacitor; and
providing a sustaining charge to the leaky capacitor.

13. The method of claim 12, wherein the step of providing the measured voltage to a scaled capacitor further comprises utilizing a plurality of current mirrors with an adjusted width and length to provide the measured voltage to the scaled capacitor.

14. A computer program product for current leakage correction for a leaky capacitor in a computer system, the computer program product having a medium with a computer program embodied thereon, the computer program comprising:
computer code for measuring voltage across the leaky capacitor;
computer code for providing the measured voltage to a scaled capacitor, wherein the scaled capacitor has an area reduced by a scaling factor in comparison to the leaky capacitor; and
computer code for providing a sustaining charge to the leaky capacitor.

15. The computer program product of claim 14, wherein the computer code for providing the measured voltage to a scaled capacitor further comprises computer code for utilizing a plurality of current mirrors with an adjusted width and length to provide the measured voltage to the scaled capacitor.

16. A circuit for current leakage correction coupled to a leaky capacitor, comprising:
a scaled capacitor, wherein the scaled capacitor has an area reduced by a scaling factor in comparison to the leaky capacitor; and
a plurality of current mirrors, wherein the plurality of current mirrors further comprise:
at least one current mirror is at least configured to be coupled to the leaky capacitor; and
at least one current mirror is at least configured to be coupled to the scaled capacitor that is at least configured to provide a potential difference across the scaled capacitor that is substantially equal to a potential difference across the leaky capacitor.

17. The circuit of claim 16, wherein the plurality of current mirror further comprises a plurality of transistors.

18. The circuit of claim 16, wherein the plurality of current mirrors further comprises a plurality of Field Effect Transistors (FET).

19. The circuit of claim 18, wherein at least one FET of the plurality of FETs is a Positive-Channel FET (PFET), wherein the PFET is at least configured to inject current into the leaky capacitor to compensate for a current leak.

20. The circuit of claim 19, wherein at least one FET of the plurality of FETs is a Negative-Channel FET (NFET).

21. The circuit of claim 18, wherein at least one FET of the plurality of FETs is a Negative-Channel FET (NFET).

22. The circuit of claim 16, wherein the plurality of current mirrors further comprise a plurality of bipolar transistors.

23. The circuit of claim 16, wherein the plurality of current mirrors further comprise a plurality of Metal-Oxide Semiconductor FETs (MOSFETs).

24. The circuit of claim 23, wherein at least one MOSFET of the plurality of MOSFETs is a Positive-type MOSFET (P-type MOSFET), wherein the P-type MOSFET is at least configured to inject current into the leaky capacitor to compensate for a current leak.

25. The circuit of claim 24, wherein at least one FET of the plurality of FETs is a Negative-type MOSFET (N-type MOSFET).

26. The circuit of claim 23, wherein at least one FET of the plurality of FETs is a Negative-Channel FET (NFET).
